(19) United States
(12) Patent Application Publication
(10) Pub. No.: US 2019/0270636 A1
(43) Pub. Date: Sep. 5, 2019

(54) PACKAGED SEMICONDUCTOR DEVICES AND METHODS FOR PRODUCING PACKAGED SEMICONDUCTOR DEVICES

(71) Applicant: Infineon Technologies AG, Neubiberg (DE)

(72) Inventors: Rainer Markus Schaller, Saal a.d. Donau (DE); Horst Theuss, Wenzenbach (DE)

(21) Appl. No.: 16/287,227

(22) Filed: Feb. 27, 2019

(30) Foreign Application Priority Data
Mar. 1, 2018 (DE) 102018203101.0

(51) Int. Cl. B81B 7/00; H01L 23/055; H01L 23/10; H01L 23/00; H01L 21/48; B81C 1/00; G01N 29/24

(52) U.S. Cl. CPC B81B 7/0041; H01L 23/055; H01L 23/10; H01L 24/73; H01L 21/4817; B81B 7/0067; B81C 2203/0145; B81C 1/00317; G01N 29/2425; H01L 2224/73265; H01L 2924/1461; B81B 2201/0214; B81C 1/00293

(57) ABSTRACT

A packaged semiconductor device comprises a semiconductor chip and a semiconductor package. The semiconductor package comprises: a metal carrier, wherein the semiconductor chip is arranged on a main surface of the metal carrier, a metal cap arranged on the main surface of the metal carrier, wherein the metal carrier and the metal cap form a cavity, wherein the semiconductor chip is arranged within the cavity, a connection conductor extending from the main surface of the metal carrier to a main surface of the semiconductor package through the metal carrier, wherein the connection conductor is electrically insulated from the metal carrier and is electrically connected to the semiconductor chip, and a connecting material arranged on a first region of the connection conductor and serving for electrically and mechanically connecting the connection conductor to an external printed circuit board, wherein at least that part of the connection conductor which extends from the main surface of the metal carrier as far as the first region of the connection conductor is formed in integral fashion.

### RELATED APPLICATION

This application claims priority under 35 U.S.C. § 119 to German Patent Application No. 102018203101.0, filed on Mar. 1, 2018, the contents of which are incorporated by reference herein in their entirety.

### TECHNICAL FIELD

The present disclosure relates generally to semiconductor technology. In particular, the disclosure relates to packaged semiconductor devices and methods for producing packaged semiconductor devices.

### BACKGROUND

In many applications, the semiconductor chips contained in semiconductor devices have to be protected against external influences. For this purpose, the semiconductor chips can be arranged in semiconductor packages and be electrically contacted from outside the semiconductor packages via connection elements. Such packaged semiconductor devices can be mounted on printed circuit boards, wherein an electrical connection between the semiconductor devices and the printed circuit boards can be effected via the connection elements. Manufacturers of semiconductor devices endeavor to provide improved packaged semiconductor devices and methods for producing such packaged semiconductor devices. In particular, it may be desirable to provide semiconductor devices which are suitable for rapid and cost-effective mounting.

### BRIEF SUMMARY

Various aspects relate to a packaged semiconductor device comprising a semiconductor chip and a semiconductor package. The semiconductor package comprises a metal carrier, wherein the semiconductor chip is arranged on a main surface of the metal carrier. Furthermore, the semiconductor package comprises a metal cap arranged on the main surface of the metal carrier, wherein the metal carrier and the metal cap form a cavity and the semiconductor chip is arranged within the cavity. The semiconductor package additionally comprises a connection conductor extending from the main surface of the metal carrier to a main surface of the semiconductor package through the metal carrier, wherein the connection conductor is electrically insulated from the metal carrier and is electrically connected to the semiconductor chip. Furthermore, the semiconductor package comprises a connecting material arranged on a first region of the connection conductor and serving for electrically and mechanically connecting the connection conductor to an external printed circuit board, wherein at least that part of the connection conductor which extends from the main surface of the metal carrier as far as the first region of the connection conductor is formed in integral fashion.

In general, the semiconductor chip can contain integrated circuits, passive electronic components, active electronic components, etc. The integrated circuits can be configured as integrated logic circuits, analog integrated circuits, integrated mixed signal circuits, integrated power circuits, etc. The semiconductor chip can be produced from an elemental semiconductor material (e.g. Si, etc.) or from a compound semiconductor material (e.g. GaN, SiC, SiGe, GaAs, etc.).

In particular the semiconductor chip can be a sensor chip including a detection structure. A sensor chip can comprise in particular a MEMS (microelectromechanical system), which can be integrated in the semiconductor chip. The MEMS can comprise one or more micromechanical structures, such as, for instance, a bridge, a membrane, a cantilever, a prong structure, etc. The MEMS can be designed to detect a physical variable, for example pressure, temperature, air humidity, etc. Examples of sensors are pressure sensors, tire pressure sensors, gas sensors, air humidity sensors, etc. In one specific example, a sensor chip can have a micromirror, for example an electromechanically operating mirror system constructed from microscopically small mirrors which can switch a light beam in optical switches. In another specific example, a sensor chip can have a photoacoustic gas sensor operating in the environment or atmosphere of a functional gas.

A sensor chip which embeds one or more micromechanical structures can comprise electronic circuits which can be designed to process electrical signals generated by the micromechanical structures. As an alternative thereto or in addition, a logic (semiconductor) chip can be coupled to a sensor chip, wherein the logic chip can be designed to process electrical signals provided by the sensor chip. By way of example, the logic chip can comprise an application specific integrated circuit (ASIC).

The metal cap and the metal carrier can be produced from a metal or a metal alloy, in particular from an iron-nickel alloy or an iron-nickel-cobalt alloy. The material can be chosen to be identical for both components. The metal carrier can have one or more holes extending from the main surface of the metal carrier to an opposite main surface of the metal carrier. The connection conductor or a plurality of connection conductors can be arranged within the holes.

In accordance with some implementations, the connecting material comprises a solderable material or a conductive adhesive. The solderable material can be a connection element composed of solder material (e.g. tin), which is not restricted to a specific geometric shape. The connection element composed of solder material can be for example a solder ball, a solder deposit, a deposited solder layer, a solder coating, a solder bead or a solder bump. In one example, connection elements in the form of solder balls can be arranged on connection conductors by means of a pick-and-place process. In a further example, preformed solder balls can be softened, forced through a nozzle and positioned at a desired location. For softening the solder balls, the solder balls can be subjected to a flash by means of a laser, for example. In yet another example, a solder coating can be deposited on the connection conductor by wave soldering. The conductive adhesive can be an isotropically conductive adhesive, in particular. In contrast to the solderable material, the curing temperature of the conductive adhesive can be significantly below the soldering temperature. Moreover, the conductive adhesive can be significantly more flexible than soldered joints formed from the solderable material.

In accordance with some implementations, that part of the connection conductor which extends from the main surface of the metal carrier as far as the main surface of the semiconductor package has a constant width. A cross section through the connection conductor in a direction parallel to the main surface of the metal carrier or perpendicular to the longitudinal extent of the connection conductor can thus be constant for this part of the connection conductor. Said part of the connection conductor can be formed in a cylindrical fashion, in particular, such that its cross section is circular. In a further example, said part of the connection conductor can be formed in a parallelepipedal fashion such that its cross section is rectangular. The connection conductor can also be referred to as “lead” or “pin”. It can be produced in particular from a metal or an associated metal alloy, for example from copper, nickel, aluminum, high-grade steel, etc.

In accordance with some implementations, an end piece of the connection conductor projects from the main surface of the semiconductor package and the connecting material is arranged on the end piece of the connection conductor. In one example, the end piece of the connection conductor projecting from the semiconductor package can have the same geometric shape as the above-described part of the connection conductor extending from the main surface of the metal carrier as far as the main surface of the semiconductor package. In one example, the entire connection conductor can be formed in an integral fashion.

In accordance with some implementations, the end piece of the connection conductor projecting from the semiconductor package widens in a direction extending away from the semiconductor package and the connecting material is arranged on the widened part of the end piece. By way of example, the end piece of the connection conductor projecting from the semiconductor package can be formed in the shape of a nail head. The basic area of the part in the shape of a nail head can be circular or rectangular. An improved electrical and mechanical connection between the connection conductor and an external printed circuit board can be ensured by the widened end piece.

In accordance with some implementations, the connection conductor projects from the main surface of the semiconductor package by less than 3 mm More precisely, the connection conductor can project from the main surface of the semiconductor package by less than 2.5 mm, less than 2.0 mm, less than 1.5 mm, less than 1.0 mm, less than 0.9 mm, less than 0.8 mm, less than 0.7 mm, less than 0.6 mm, less than 0.5 mm, less than 0.4 mm, less than 0.3 mm, less than 0.2 mm, or less than 0.1 mm. In one example, the connection conductor, rather than projecting from the main surface of the semiconductor package, can terminate flush therewith or form a common plane therewith. In a further example, the connection conductor can be inserted into the semiconductor package or the metal carrier. In this case, the conductive connecting material can extend into the metal carrier and electrically contact the connection conductor within the metal carrier. An electrical contacting of the connection conductor or of the semiconductor chip can then be effected via the connecting material projecting from the semiconductor package.

In accordance with some implementations, the packaged semiconductor device comprises an electrically insulating layer arranged on a second main surface of the metal carrier, said second main surface being situated opposite the first main surface of the metal carrier, said electrically insulating layer electrically insulating the connecting material and the metal carrier from one another. The electrically insulating layer can have a thickness of 0.01 mm to 2.00 mm.

In accordance with some implementations, the electrically insulating layer comprises a printed circuit board material, a soldering mask, a ceramic material, a glass material, an epoxy-based material and/or a polyimide. The printed circuit board material can be in particular a laminate (e.g. FR-4). The polyimide can be Kapton, in particular.

In accordance with some implementations, the packaged semiconductor device comprises a glass seal arranged between that part of the connection conductor which extends through the metal carrier and the metal carrier, said glass seal electrically insulating the metal carrier and the connection conductor from one another. In this case, the connecting surfaces between the connection conductor and the glass seal and between the metal carrier and the glass seal can terminate in an air-tight fashion, in particular, such that the metal carrier, the metal cap and possible further components can form a hermetically sealed cavity.

In accordance with some implementations, the semiconductor device is a surface mount component or a surface mountable component. In contrast to through hole technology (THT) components, surface mount components can be soldered directly onto a printed circuit board by means of solderable connection surfaces.

In accordance with some implementations, the cavity is hermetically sealed. A hermetically sealed cavity may be necessary in particular for applications which should be operated in a specific gas environment or gas atmosphere. The gases situated in the hermetically sealed cavity can be protective gases, filling gases or functional gases. In one example, the hermetically sealed cavity can be formed by the metal carrier and the metal cap alone. In a further example, the cavity can be formed by the metal carrier, the metal cap and possible further components (e.g. glass windows or glass seals in the metal carrier).

In accordance with some implementations, the cavity contains a functional gas and the semiconductor package contains a photoacoustic sensor.

In accordance with some implementations, the metal cap has an optical window and the semiconductor chip is provided for an optical application.

Various aspects relate to a packaged semiconductor device comprising a semiconductor chip and a semiconductor package. The semiconductor package comprises a metal carrier having a first main surface and a second main surface situated opposite the first main surface, wherein the semiconductor chip is arranged on the first main surface. Furthermore, the semiconductor package comprises a metal cap arranged on the first main surface of the metal carrier, wherein the metal carrier and the metal cap form a cavity and the semiconductor chip is arranged within the cavity. The semiconductor package furthermore comprises a connection conductor extending from the first main surface of the metal carrier to the second main surface of the metal carrier through the metal carrier, wherein the connection conductor is electrically connected to the semiconductor chip. Furthermore, the semiconductor package comprises a redistribution layer arranged on the second main surface of the metal carrier, said redistribution layer electrically connecting the connection conductor to a connection element of the semiconductor package, wherein the connection conductor and the connection element are offset laterally with respect to one another as viewed in a direction perpendicular to the main surface of the metal carrier.

The redistribution layer can contain one or more conductor tracks in the form of metal layers or metal tracks, which can extend substantially parallel to the second main surface of the metal carrier. The conductor tracks can fulfil the function of a redistribution wiring or redistribution for electrically coupling the connection conductor(s) to external contact elements of the packaged semiconductor device. In other words, the conductor tracks can be designed to make the connection conductors available at other positions of the semiconductor device. A multiplicity of dielectric layers can be arranged between the multiplicity of conductor tracks in order to electrically insulate the conductor tracks from one another. Furthermore, metal layers arranged on different planes can be electrically connected to one another by a multiplicity of plated-through holes (or vias).

In accordance with some implementations, the redistribution layer has a thickness of 1 μm to 1 mm More precisely, the redistribution layer can have a thickness of 1 μm to 800 μm, of 1 μm to 600 μm, of 1 μm to 400 μm, or of 1 μm to 200 μm. The thickness of the redistribution layer depends on the number of dielectric layers and conductor track layers that it contains. In one example, the number of dielectric layers can lie in a range of 1 to 3 and the number of layers having conductor tracks can lie in a range of 1 to 4.

In accordance with some implementations, the metal carrier has a thickness of less than 1 mm More precisely, the metal carrier can have a thickness of less than 800 μm or less than 600 μm.

Various aspects relate to a method for producing a packaged semiconductor device. The method comprises providing a metal carrier having a first main surface and a second main surface situated opposite the first main surface, wherein a hole extends from the first main surface to the second main surface through the metal carrier. Furthermore, the method comprises coating a connection conductor at least partly with a glass solder material. The method furthermore comprises arranging the part of the connection conductor coated with the glass solder material in the hole in the metal carrier. Furthermore, the method comprises heating the glass solder material, thereby forming a glass seal connecting the connection conductor to the sidewalls of the hole. Furthermore, the method comprises arranging a connecting material on the connection conductor for electrically and mechanically connecting the connection conductor to an external printed circuit board.

In accordance with some implementations, the method comprises welding a metal cap onto the metal carrier, wherein a semiconductor chip is arranged on the metal carrier and whereby a hermetically sealed cavity is formed by the metal carrier and the metal cap. In particular, the metal cap can be fitted to the metal carrier by resistance welding. In this case, current pulses can be applied to the welding region between the metal cap and the metal carrier, wherein electrical point effects occur. The material of the components to be connected can melt and a fixed connection between the components can be formed. The resistance welding can be carried out at room temperature, wherein the high temperatures required for the welding remain limited to the welding region.

In accordance with some implementations, arranging the connecting material on the connection conductor comprises a pick-and-place process or a wave soldering process.

Various aspects relate to a method for producing a packaged semiconductor device. The method comprises providing a semiconductor package. The semiconductor package comprises a metal carrier and a metal cap arranged on a main surface of the metal carrier, wherein the metal carrier and the metal cap form a cavity. Furthermore, the semiconductor package comprises a semiconductor chip arranged on the main surface of the metal carrier and within the cavity. The semiconductor package furthermore comprises a connection conductor extending from the main surface of the metal carrier to a main surface of the semiconductor package through the metal carrier, wherein the connection conductor is electrically connected to the semiconductor chip, and wherein an end piece of the connection conductor projects from the main surface of the semiconductor package. Furthermore, the method comprises shortening the end piece of the connection conductor. Furthermore, the method comprises applying a connecting material on the shortened end piece of the connection conductor.

### BRIEF DESCRIPTION OF THE DRAWINGS

The accompanying drawings serve to deepen understanding of aspects of the present disclosure. The drawings illustrate implementations and together with the description serve to elucidate the principles of said aspects. The elements of the drawings need not necessarily be true to scale relative to one another. Identical reference signs designate corresponding similar parts.

FIG. 1 schematically shows a lateral cross-sectional view of a packaged semiconductor device 100 in accordance with the disclosure. The semiconductor device 100 comprises connection conductors on which a connecting material is arranged.

FIG. 2 schematically shows a lateral cross-sectional view of a packaged semiconductor device 200 in accordance with the disclosure. The semiconductor device 200 comprises connection conductors which are electrically connected to a redistribution layer.

FIG. 3 schematically shows a lateral cross-sectional detail view of a packaged semiconductor device 300 in accordance with the disclosure. The semiconductor device 300 comprises a connection conductor on which a connecting material in the form of a solder ball is arranged.

FIG. 4 schematically shows a lateral cross-sectional detail view of a packaged semiconductor device 400 in accordance with the disclosure. The semiconductor device 400 comprises a connection conductor on which a connecting material in the form of a solder layer is arranged.

FIG. 5 schematically shows a lateral cross-sectional detail view of a packaged semiconductor device 500 in accordance with the disclosure. The semiconductor device 500 comprises a connection conductor on which a connecting material in the form of a solder ball is arranged.

FIG. 6 schematically shows a lateral cross-sectional detail view of a packaged semiconductor device 600 in accordance with the disclosure. The semiconductor device 600 comprises a connection conductor on which a connecting material in the form of a solder layer is arranged.

FIG. 7 schematically shows a lateral cross-sectional detail view of a packaged semiconductor device 700 in accordance with the disclosure. The semiconductor device 700 comprises a connection conductor having a widened end piece on which a connecting material in the form of a solder layer is arranged.

FIG. 8 schematically shows a lateral cross-sectional detail view of a packaged semiconductor device 800 in accordance with the disclosure. The semiconductor device 800 comprises a connection conductor having a widened end piece on which a connecting material in the form of a solder layer is arranged. Furthermore, the semiconductor device 800 comprises an electrically insulating layer which electrically insulates the connecting material and a metal carrier of the semiconductor device 800 from one another.

FIG. 9 schematically shows a lateral cross-sectional detail view of a packaged semiconductor device 900 in accordance with the disclosure. The semiconductor device 900 comprises a connection conductor on which a connecting material in the form of a solder ball is arranged. Furthermore, the semiconductor device 900 comprises an electrically insulating layer which electrically insulates the connecting material and a metal carrier of the semiconductor device 900 from one another.

FIG. 10 schematically shows a lateral cross-sectional detail view of a packaged semiconductor device 1000 in accordance with the disclosure. The semiconductor device 1000 comprises a connection conductor which is electrically connected to a redistribution layer. Contact pads are arranged on the underside of the redistribution layer.

FIG. 11 schematically shows a lateral cross-sectional detail view of a packaged semiconductor device 1100 in accordance with the disclosure. The semiconductor device 1100 comprises a connection conductor which is electrically connected to a redistribution layer. Solder deposits are arranged on the underside of the redistribution layer.

FIGS. 12A to 12C schematically illustrate cross-sectional side views of a method for producing a packaged semiconductor device 1200 in accordance with the disclosure.

FIGS. 13A to 13E schematically illustrate cross-sectional side views of a method for producing a packaged semiconductor device in accordance with the disclosure.

### DETAILED DESCRIPTION

In the following detailed description, reference is made to the accompanying drawings, which show for illustration purposes specific aspects and implementations in which the disclosure can be implemented in practice. In this context, direction terms such as, for example, “at the top”, “at the bottom”, “at the front”, “at the back”, etc. can be used with respect to the orientation of the figures described. Since the components of the implementations described can be positioned in different orientations, the direction terms can be used for illustration purposes and are not restrictive in any way whatsoever. Other aspects can be used and structural or logical changes can be made, without departing from the concept of the present disclosure. That is to say that the following detailed description should not be understood in a restrictive sense.

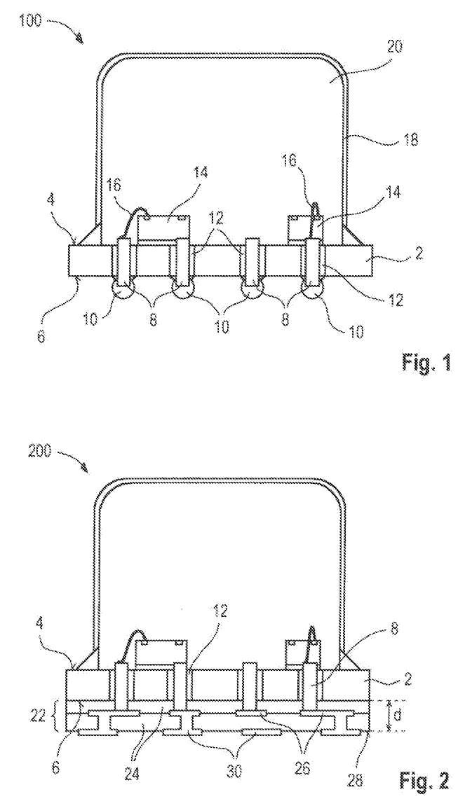

FIG. 1 schematically shows a lateral cross-sectional view of a packaged semiconductor device 100 in accordance with the disclosure. The semiconductor device 100 comprises a metal carrier 2 having an upper main surface 4 and an opposite lower main surface 6. In the example in FIG. 1, the lower main surface 6 of the metal carrier 2 simultaneously corresponds to a lower main surface of the semiconductor device 100 or of the semiconductor package. One or more connection conductors 8 extend through the metal carrier 2 from the upper main surface 4 to the lower main surface 6. Four connection conductors 8 are illustrated by way of example in FIG. 1. In further examples, the number of connection conductors 8 can also be larger or smaller, depending on the application. Those parts of the connection conductors 8 which extend from the upper main surface 4 as far as the lower main surface 6 can have a constant width. In the example in FIG. 1, the connection conductors 8 each project from the upper main surface 4 and the lower main surface 6. In further examples, the connection conductors 8 can terminate flush with the respective main surface or else be inserted into the metal carrier 2 or into the semiconductor package.

A respective connecting material 10 is arranged on the end pieces of the connection conductors 8 projecting from the lower main surface 6 of the metal carrier 2. The connecting material 10 can be designed to electrically and mechanically connect the connection conductors 8 to an external printed circuit board (not illustrated). The semiconductor device 100 can be a surface mount component on account of the arrangement of the connection conductors 8 and the connecting material 10. In FIG. 1, the connecting material 10 is illustrated by way of example in the form of solder balls. Respective glass seals 12 are arranged between that part of the connection conductors 8 which extends through the metal carrier 2 and the metal carrier 2. The glass seals 12 can electrically insulate the metal carrier 2 from the connecting material 10 and/or can electrically insulate the metal carrier 2 from the connection conductors 8.

The semiconductor device 100 comprises one or more semiconductor chips 14, which can be arranged on the upper main surface 4 of the metal carrier 2. Two semiconductor chips 14 are illustrated by way of example in FIG. 1. In further examples, the number of semiconductor chips 14 can also be larger or smaller, depending on the application. The two semiconductor chips 14 in FIG. 1 can be a sensor chip and a logic chip, for example. The semiconductor chips 14 can be electrically connected to one another for intercommunication. The semiconductor chips 14 are each electrically connected to one or more connection conductors 8. Consequently, the semiconductor chips 14 can be electrically contacted from outside the semiconductor package via the connecting material 10 and the connection conductors 8. In FIG. 1, the semiconductor chips 14 are electrically connected to the connection conductors 8 via bond wires 16, for example.

The semiconductor device 100 comprises a metal cap 18 arranged on the upper main surface 4 of the metal carrier 2. The metal carrier 2 and the metal cap 18 can form a cavity 20, wherein the semiconductor chips 14 are arranged within the cavity 20. The cavity 20 can be in particular hermetically sealed. In particular a gas atmosphere or gas environment can be formed in the cavity 20, for example by a protective gas, a filling gas or a functional gas. The semiconductor device 100 can comprise further optional components, which are not illustrated in FIG. 1. By way of example, a material (e.g. a glob-top material) can be applied on one or both of the semiconductor chips 14 in order to protect it/them from external influences.

FIG. 2 schematically shows a lateral cross-sectional view of a packaged semiconductor device 200 in accordance with the disclosure. The semiconductor device 200 has components similar in part to the semiconductor device 100 from FIG. 1. In comparison with FIG. 1, the semiconductor device 200 comprises a redistribution layer 22 comprising one or more dielectric layers 24 and one or more metal layers 26. A thickness d of the redistribution layer 22 can lie in a range of approximately 1 μm to approximately 1 mm More precisely, the redistribution layer 22 can have a thickness d of 1 μm to 800 μm, of 1 μm to 600 μm, of 1 μm to 400 μm, or of 1 μm to 200 μm. The connection conductors 8 projecting from the lower main surface 6 of the metal carrier 2 can extend into the redistribution layer 22 and be electrically connected to contact pads or metal layers within the redistribution layer 22. In one example, the connection conductors 8 can be plugged into through holes in the redistribution layer 22 in the manner of a plug connection. In a further example, the connection conductors 8 can be adhesively bonded or soldered onto the contact pads or the metal layers within the redistribution layer 22.

Connection elements 30 are arranged on the lower main surface 28 of the redistribution layer 22, which connection elements can be designed to electrically and mechanically connect the semiconductor device 200 to a printed circuit board (not illustrated). The connection elements 30 can thus be produced in particular from a solderable material. In the example in FIG. 2, the connection elements 30 are illustrated in the form of contact pads or “landing pads”. By means of the redistribution layer 22, the connection conductors 8 are made available at desired positions on the lower main surface 28 of the redistribution layer 22. In this case, at least one of the connection conductors 8 and the connection element 30 electrically connected to it are offset laterally with respect to one another as viewed in a direction perpendicular to one of the main surfaces 4 and 6 of the metal carrier 2 or perpendicular to the lower main surface 28 of the redistribution layer 22. The semiconductor device 200 can be in particular a surface mount component.

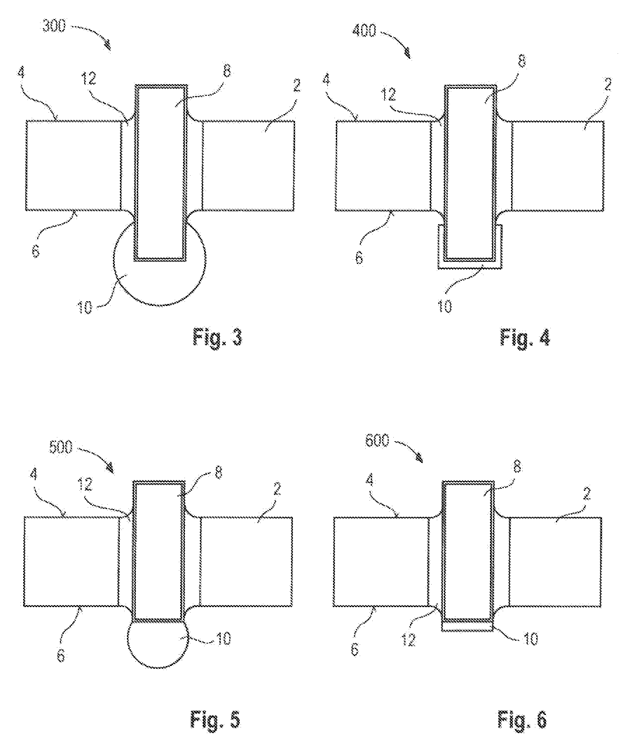

FIG. 3 schematically shows a lateral cross-sectional detail view of a packaged semiconductor device 300 in accordance with the disclosure. FIG. 3 can be for example a detail of the semiconductor device 100 from FIG. 1, wherein some components of the semiconductor device 300 are not illustrated for the sake of simplicity. FIG. 3 shows a metal carrier 2 having a connection conductor 8 extending from an upper main surface 4 to a lower main surface 6 of the metal carrier 2. Glass seals 12 are arranged between the connection conductor 8 and the metal carrier 2 for the purpose of electrical insulation. A connecting material 10 is arranged on the connection conductor 8 projecting from the lower main surface 6 of the metal carrier 2. In the example in FIG. 3, the connecting material 10 is present in the form of a solder ball which can contact the underside and the side surfaces of the connection conductor 8. The solder ball can be arranged on the connection conductor 8 by means of a pick-and-place process, for example.

FIG. 4 schematically shows a lateral cross-sectional detail view of a packaged semiconductor device 400 in accordance with the disclosure. The semiconductor device 400 can be similar to the semiconductor device 300 from FIG. 3. In contrast thereto, the semiconductor device 400 comprises a connecting material 10 in the form of a solder layer which can be deposited on the connection conductor 8 for example by means of a wave soldering process.

FIG. 5 schematically shows a lateral cross-sectional detail view of a packaged semiconductor device 500 in accordance with the disclosure. The semiconductor device 500 can be similar to the semiconductor device 300 from FIG. 3. In contrast thereto, the semiconductor device 500 comprises shortened connection conductors 8, wherein the side surfaces of the lower end piece of the connection conductor 8 can be completely covered with the material of the glass seal 12. Accordingly, the solder ball of the semiconductor device 500 has smaller dimensions and can exclusively cover the underside of the connection conductor 8. The side surfaces of the connection conductor 8 can be left such that they are not covered by the connecting material 10.

FIG. 6 schematically shows a lateral cross-sectional detail view of a packaged semiconductor device 600 in accordance with the disclosure. The semiconductor device 600 can be similar to the semiconductor device 400 from FIG. 4. In comparison therewith, the semiconductor device 600 comprises a shortened connection conductor 8, wherein the side surfaces of the lower end piece of the connection conductor 8 can be completely covered with the material of the glass seal 12. Accordingly, the solder layer of the semiconductor device 600 can exclusively cover the underside of the connection conductor 8. The side surfaces of the connection conductor 8 can be left such that they are not covered by the connecting material 10.

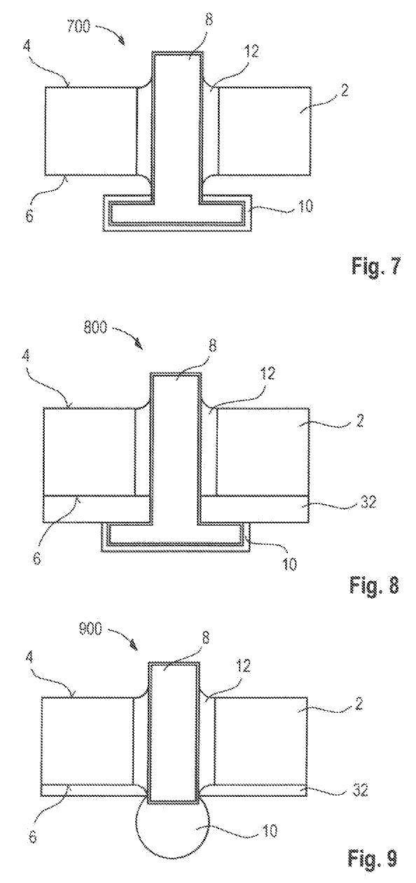

FIG. 7 schematically shows a lateral cross-sectional detail view of a packaged semiconductor device 700 in accordance with the disclosure. The end piece of the connection conductor 8 projecting from the metal carrier 2 or from the semiconductor package of the semiconductor device 700 can widen in a direction extending away from the lower main surface 6 of the metal carrier 2. In the example in FIG. 7, the end piece of the connection conductor 8 is formed in the shape of a nail head. The basic area of the part in the shape of a nail head can have a circular or rectangular shape, for example, as viewed from below. The connecting material 10 can be arranged in particular on the widened part of the connection conductor 8. In the example in FIG. 7, the connecting material 10 in the form of a solder layer covers the underside, the side surfaces and the top side of the end piece of the connection conductor 8. In a further example, the connecting material 10 can also cover only the underside of the end piece or only the underside and the side surfaces of the end piece. The widened end piece makes it possible to provide an enlarged connection surface on the underside of the connection conductor 8. The electrical and mechanical connection of the connection conductor 8 to an external printed circuit board (not illustrated) can be improved as a result.

FIG. 8 schematically shows a lateral cross-sectional detail view of a packaged semiconductor device 800 in accordance with the disclosure. The semiconductor device 800 can be similar to the semiconductor device 700 from FIG. 7. In comparison therewith, the semiconductor device 800 can additionally comprise an electrically insulating layer 32 arranged on the lower main surface 6 of the metal carrier 2. The insulation layer 32 can be designed in particular to electrically insulate the connection conductor 8 and the metal carrier 2 from one another and/or to electrically insulate the connecting material 10 and the metal carrier 2 from one another. The insulation layer 32 can comprise for example a printed circuit board material (e.g. FR-4), a soldering mask, a ceramic material, a glass material, an epoxy-based material or a polyimide (e.g. Kapton).

FIG. 9 schematically shows a lateral cross-sectional detail view of a packaged semiconductor device 900 in accordance with the disclosure. The semiconductor device 900 can be similar to the semiconductor device 500 from FIG. 5. In contrast thereto, the semiconductor device 900 additionally comprises an electrically insulating layer 32 such as has already been described in association with FIG. 8.

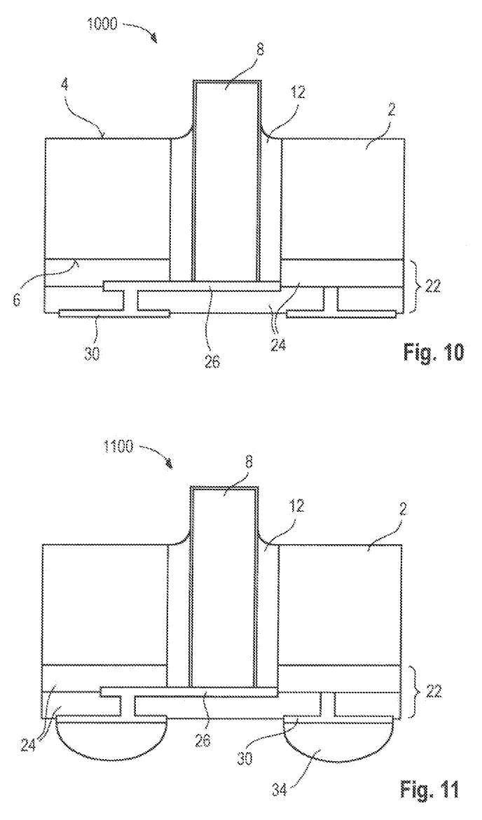

FIG. 10 schematically shows a lateral cross-sectional detail view of a packaged semiconductor device 1000 in accordance with the disclosure. FIG. 10 can be for example a detail of the semiconductor device 200 from FIG. 2, wherein some components of the semiconductor device 1000 are not illustrated for the sake of simplicity. The statements made in connection with the semiconductor device 200 from FIG. 2 can accordingly be applied to the semiconductor device 1000 in FIG. 10.

FIG. 11 schematically shows a lateral cross-sectional detail view of a packaged semiconductor device 1100 in accordance with the disclosure. The semiconductor device 1100 can be similar to the semiconductor device 1000 from FIG. 10. In contrast thereto, the semiconductor device 1100 additionally comprises connection elements 34, which can be arranged on the contact pads (“landing pads”) 30. In the example in FIG. 11, the connection elements 34 are illustrated in the form of solder deposits which can be designed to electrically and mechanically connect the semiconductor device 1100 to a printed circuit board (not illustrated).

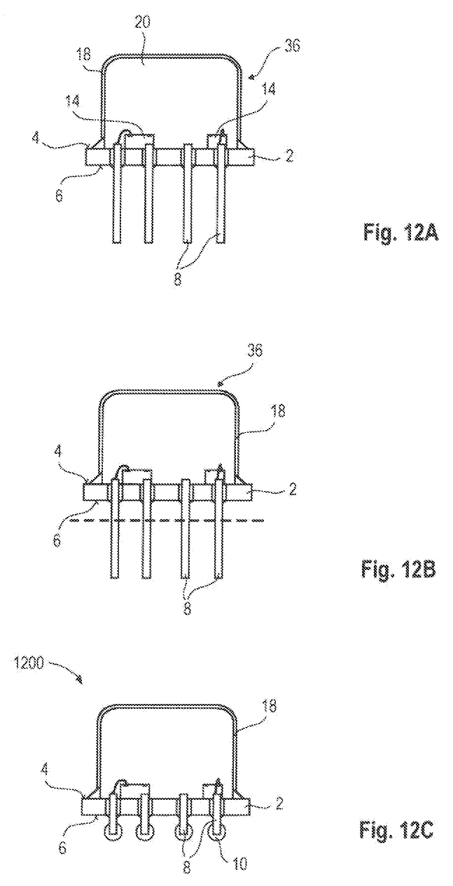

FIGS. 12A to 12C schematically illustrate lateral cross-sectional views of a method for producing a packaged semiconductor device 1200 in accordance with the disclosure. The semiconductor device 1200 produced can be similar for example to the semiconductor device 100 from FIG. 1.

In FIG. 12A, a semiconductor package 36 is provided. The semiconductor package 36 comprises a metal carrier 2 and a metal cap 18 arranged on the upper main surface 4 of the metal carrier 2, wherein the metal carrier 2 and the metal cap 18 form a cavity 20. Semiconductor chips 14 are arranged on the upper main surface 4 of the metal carrier 2 and within the cavity 20. The semiconductor package 36 furthermore comprises connection conductors 8 extending from the upper main surface 4 of the metal carrier 2 to the lower main surface 6 of the metal carrier 2 or of the semiconductor package 36 through the metal carrier 2, wherein the semiconductor chips 14 are in each case electrically connected to the connection conductors 8. End pieces of the connection conductors 8 project from the lower main surface 6 of the semiconductor package 36. Two semiconductor chips 14 and four connection conductors 8 are illustrated by way of example in FIG. 12A. In further examples, the number of semiconductor chips and connection conductors can deviate from the example in FIG. 12A, depending on the application.

In FIG. 12B, the end pieces of the connection conductors 8 are shortened. In this case, the shortened end pieces of the connection conductors 8 can project from the lower main surface 6 of the semiconductor package 36 by less than 3 mm More precisely, the connection conductors 8 can project from the lower main surface 6 of the semiconductor package 36 by less than 2.5 mm, less than 2.0 mm, less than 1.5 mm, less than 1.0 mm, less than 0.9 mm, less than 0.8 mm, less than 0.7 mm, less than 0.6 mm, less than 0.5 mm, less than 0.4 mm, less than 0.3 mm, less than 0.2 mm, or less than 0.1 mm.

In FIG. 12C, a connecting material 10 is arranged on each of the end pieces of the connection conductors 8 projecting from the semiconductor package 36. In the example in FIG. 12C, the connecting material 10 is illustrated in the form of solder balls. The connecting material 10 can be designed to electrically and mechanically connect the connection conductors 8 or the semiconductor device 1200 produced to an external printed circuit board (not illustrated).

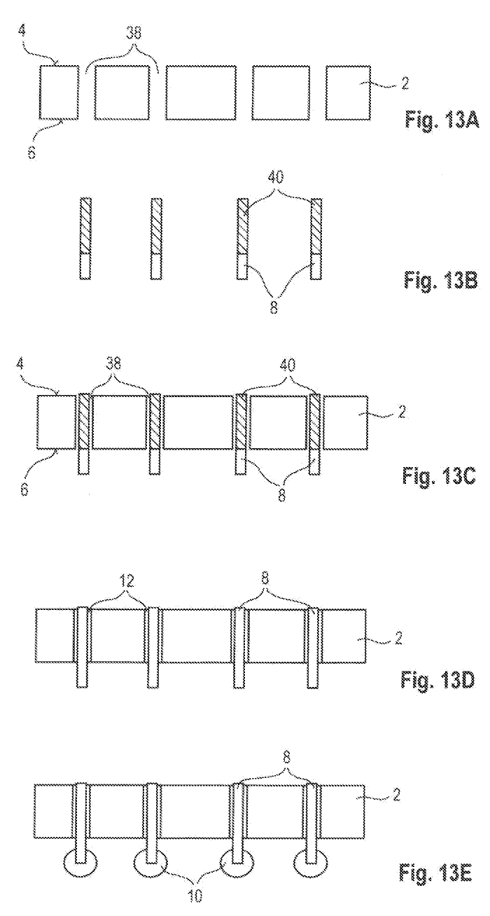

FIGS. 13A to 13E schematically illustrate lateral cross-sectional views of a method for producing a packaged semiconductor device in accordance with the disclosure.

In FIG. 13A, a metal carrier 2 having a first main surface 4 and a second main surface 6 situated opposite the first main surface 4 is provided. One or more holes 38 extend from the first main surface 4 to the second main surface 6 through the metal carrier 2. In this case, the sectional plane in FIG. 13A extends through the holes 38. Four holes 38 in the metal carrier 2 are illustrated by way of example in FIG. 13A. In further examples, the number of holes can deviate from the example in FIG. 13A, depending on the application.

In FIG. 13B, one or more connection conductors 8 are coated at least partly with a glass solder material 40. Since the connection conductors 8 are positioned in the holes 38 in the metal carrier 2 at a later point in time, the number of connection conductors 8 can correspond in particular to the number of holes 38 in the metal carrier 2. In one example, the glass solder material 40 can be deposited on the connection conductors 8 in the form of a layer. In a further example, the glass solder material 40 can be slipped over the connection conductors 8 in the form of small sleeves or small tubes.

In FIG. 13C, those parts of the connection conductors 8 which are coated with the glass solder material 40 are positioned in the holes 38 in the metal carrier 2. In the example in FIG. 13C, the connection conductors 8 each project beyond the main surfaces 4 and 6 of the metal carrier 2. In a further example, the connection conductors 8 need not project beyond the main surfaces 4 and 6, but rather can terminate flush with one or both of the main surfaces 4 and 6 or form a common plane. In a further example, the connection conductors 8 can be inserted into the metal carrier 2 at one or both of the main surfaces 4 and 6.

In FIG. 13D, the glass solder material 40 is heated, thereby forming glass seals 12. The glass seals 12 connect the respective connection conductor 8 to the sidewalls of the respective hole 38.

In FIG. 13E, a connecting material 10 is arranged on the connection conductors 8, said connecting material being designed for electrically and mechanically connecting the connection conductors 8 to an external printed circuit board (not illustrated). The connecting material 10 can be arranged on the connection conductors 8 for example by means of a pick-and-place process or a wave soldering process.

The method shown in FIGS. 13A-13E can comprise further optional steps, which are not explicitly illustrated for the sake of simplicity. By way of example, in a further step, one or more semiconductor chips (not illustrated) can be arranged on the metal carrier 2. In a further step, the semiconductor chip(s) can be electrically connected to the connection conductors 8. In another further step, a metal cap (not illustrated) can be welded onto the metal carrier, whereby a hermetically sealed cavity can be formed by the metal carrier and the metal cap.

Within the meaning of the present description, the terms “connected”, “coupled”, “electrically connected” and/or “electrically coupled” need not necessarily mean that components must be directly connected or coupled to one another. Intervening components can be present between the “connected”, “coupled”, “electrically connected” or “electrically coupled” components.

Furthermore, the word “above” used for example with respect to a material layer that is formed “above” a surface of an object or is situated “above” said surface can be used in the present description in the sense that the material layer is arranged (for example formed, deposited, etc.) “directly on”, for example in direct contact with, the surface meant. The word “above” used for example with respect to a material layer that is formed or arranged “above” a surface can also be used in the present text in the sense that the material layer is arranged (e.g. formed, deposited, etc.) “indirectly on” the surface meant, wherein for example one or more additional layers are situated between the surface meant and the material layer.

In so far as the terms “have”, “contain”, “encompass”, “with” or variants thereof are used either in the detailed description or in the claims, these terms are intended to be inclusive in a similar manner to the term “comprise”. That means that within the meaning of the present description the terms “have”, “contain”, “encompass”, “with”, “comprise” and the like are open terms which indicate the presence of stated elements or features but do not exclude further elements or features. The articles “a/an” or “the” should be understood such that they include the plural meaning and also the singular meaning, unless the context clearly suggests a different understanding.

Furthermore, the word “exemplary” is used in the present text in the sense that it serves as an example, a case or an illustration. An aspect or a design that is described as “exemplary” in the present text should not necessarily be understood in the sense as though it has advantages over other aspects or designs. Rather, the use of the word “exemplary” is intended to present concepts in a concrete manner Within the meaning of this application, the term “or” does not mean an exclusive “or”, but rather an inclusive “or”. That is to say that, unless indicated otherwise or unless a different interpretation is allowed by the context, “X uses A or B” means each of the natural inclusive permutations. That is to say if X uses A, X uses B or X uses both A and B, then “X uses A or B” is fulfilled in each of the cases mentioned above. Moreover, the articles “a/an” can be interpreted within the meaning of this application and the accompanying claims generally as “one or more”, unless it is expressly stated or clearly evident from the context that only a singular is meant. Furthermore, at least one from A and B or the like generally means A or B or both A and B.

Devices and methods for producing devices are described in the present text. Observations made in connection with a device described can also apply to a corresponding method, and vice versa. If a specific component of a device is described, for example, then a corresponding method for producing the device can contain a process for providing the component in a suitable manner, even if such a process is not explicitly described or illustrated in the figures. Moreover, the features of the various example aspects described in the present text can be combined with one another, unless expressly noted otherwise.

Although the disclosure has been shown and described with respect to one or more implementations, equivalent alterations and modifications based at least in part on the reading and understanding of this description and the accompanying drawings will be apparent to the person skilled in the art. The disclosure includes all such modifications and alterations and is restricted solely by the concept of the following claims. Especially with respect to the various functions that are implemented by the above-described components (for example elements, resources, etc.), the intention is that, unless indicated otherwise, the terms used for describing such components correspond to any components which implement the specified function of the described component (which is functionally equivalent, for example), even if it is not structurally equivalent to the disclosed structure which implements the function of the example implementations of the disclosure as presented herein. Furthermore, even if a specific feature of the disclosure has been disclosed with respect to only one of various implementations, such a feature can be combined with one or more other features of the other implementations in a manner such as is desired and advantageous for a given or specific application.

1. A packaged semiconductor device, comprising:
a semiconductor chip; and
a semiconductor package, comprising:
a metal carrier, wherein the semiconductor chip is arranged on a main surface of the metal carrier,
a metal cap arranged on the main surface of the metal carrier, wherein the metal carrier and the metal cap form a cavity, wherein the semiconductor chip is arranged within the cavity,
a connection conductor extending from the main surface of the metal carrier to a main surface of the semiconductor package through the metal carrier, wherein the connection conductor projects from the main surface of the semiconductor package by less than 3 mm, wherein the connection conductor is electrically insulated from the metal carrier and is electrically connected to the semiconductor chip, and
a connecting material arranged on a first region of the connection conductor and serving for electrically and mechanically connecting the connection conductor to an external printed circuit board, wherein at least that part of the connection conductor which extends from the main surface of the metal carrier as far as the first region of the connection conductor, is formed in integral fashion, wherein an end piece of the connection conductor projects from the main surface of the semiconductor package and the connecting material is arranged on the end piece of the connection conductor.

2. The packaged semiconductor device as claimed in claim 1, wherein the connecting material comprises a solderable material or a conductive adhesive.

3. The packaged semiconductor device as claimed in claim 1, wherein that part of the connection conductor which extends from the main surface of the metal carrier to the main surface of the semiconductor package has a constant width.

4. The packaged semiconductor device as claimed in claim 1, wherein the end piece of the connection conductor projecting from the semiconductor package widens in a direction extending away from the semiconductor package and the connecting material is arranged on the widened part of the end piece.

5. The packaged semiconductor device as claimed in claim 1, wherein the main surface of the metal carrier is a first main surface, and wherein the packaged semiconductor device further comprises an electrically insulating layer arranged on a second main surface of the metal carrier, wherein the second main surface is situated opposite the first main surface of the metal carrier, wherein the electrically insulating layer electrically insulates the connecting material and the metal carrier from one another.

6. The packaged semiconductor device as claimed in claim 5, wherein the electrically insulating layer comprises a printed circuit board material, a soldering mask, a ceramic material, a glass material, an epoxy-based material, or a polyimide.

7. The packaged semiconductor device as claimed in claim 1, further comprising a glass seal arranged between that part of the connection conductor which extends through the metal carrier and the metal carrier, wherein the glass seal electrically insulates the metal carrier and the connection conductor from one another.

8. The packaged semiconductor device as claimed in claim 1, wherein the packaged semiconductor device is a surface mount component.

9. The packaged semiconductor device as claimed in claim 1, wherein the cavity is hermetically sealed.

10. The packaged semiconductor device as claimed in claim 1, wherein the cavity contains a functional gas and the semiconductor package contains a photoacoustic sensor.

11. The packaged semiconductor device as claimed in claim 1, wherein the metal cap has an optical window and the semiconductor chip is provided for an optical application.

12. A packaged semiconductor device, comprising:
a semiconductor chip; and
a semiconductor package; comprising:
a metal carrier having a first main surface and a second main surface situated opposite the first main surface, wherein the semiconductor chip is arranged on the first main surface,
a metal cap arranged on the first main surface of the metal carrier, wherein the metal carrier and the metal cap form a cavity, wherein the semiconductor chip is arranged within the cavity,
a connection conductor formed in an integral fashion and extending from the first main surface of the metal carrier to the second main surface of the metal carrier through the metal carrier, wherein the connection conductor is electrically connected to the semiconductor chip, and
a redistribution layer arranged directly on the second main surface of the metal carrier, wherein the redistribution layer electrically connects the connection conductor to a connection element of the semiconductor package, wherein the connection conductor and the connection element are offset laterally with respect to one another as viewed in a direction perpendicular to the main surface of the metal carrier, wherein the redistribution layer comprises at least one dielectric layer and at least one metal layer.

13. The packaged semiconductor device as claimed in claim 12, wherein the redistribution layer has a thickness of 1 μm to 1 mm.

14. The packaged semiconductor device as claimed in claim 12, wherein the metal carrier has a thickness of less than 1 mm.

15. A method for producing a packaged semiconductor device, the method comprising:
providing a metal carrier having a first main surface and a second main surface situated opposite the first main surface, wherein a hole extends from the first main surface to the second main surface through the metal carrier;
coating a part of a connection conductor with a glass solder material;
arranging the part of the connection conductor coated with the glass solder material in the hole in the metal carrier;
heating the glass solder material to form a glass seal connecting the connection conductor to sidewalls of the hole; and
arranging a connecting material on the connection conductor to electrically and mechanically connect the connection conductor to an external printed circuit board,
wherein, before heating the glass solder material, the connection conductor has a length such that the connection conductor projects from a main surface of a semiconductor package of the packaged semiconductor device produced by less than 3 mm.

16. The method as claimed in claim 15, further comprising welding a metal cap onto the metal carrier, wherein a semiconductor chip is arranged on the metal carrier and whereby a hermetically sealed cavity is formed by the metal carrier and the metal cap.

17. The method as claimed in claim 15, wherein arranging the connecting material on the connection conductor comprises a pick-and-place process or a wave soldering process.

18. A method for producing a packaged semiconductor device, the method comprising:
providing a semiconductor package, wherein the semiconductor package comprises:
a metal carrier;
a metal cap arranged on a main surface of the metal carrier, wherein the metal carrier and the metal cap form a cavity;
a semiconductor chip arranged on the main surface of the metal carrier and within the cavity;
a connection conductor extending from the main surface of the metal carrier to a main surface of the semiconductor package through the metal carrier, wherein the connection conductor is electrically connected to the semiconductor chip, and wherein an end piece of the connection conductor projects from the main surface of the semiconductor package;
shortening the end piece of the connection conductor; and
applying a connecting material on the shortened end piece of the connection conductor, wherein the connection conductor projects from the main surface of the semiconductor package by less than 3 mm.

19. The method of claim 18, wherein a part of the connection conductor, which extends from the main surface of the metal carrier to the main surface of the semiconductor package, has a constant width.

20. The method of claim 18, wherein the cavity is hermetically sealed.
